(19) United States
(12) Patent Application Publication
(10) Pub. No.: US 2008/0252410 A1
(43) Pub. Date: Oct. 16, 2008

(54) RESISTOR STRUCTURE AND FABRICATING METHOD THEREOF

(76) Inventor: Hung-Sung Lin, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/735,503

(22) Filed: Apr. 16, 2007

(51) Int. Cl. H01C 7/10; H01L 21/62; H01L 29/10

(52) U.S. Cl. 338/20; 438/382; 257/E29.06; 257/E21.395

(57) ABSTRACT

A resistor structure includes a substrate, a well of a predetermined conductive type positioned in the substrate, a gate structure positioned on the substrate, a first doping region of the predetermined conductive type positioned at a first side of the gate structure, a second doping region of the predetermined conductive type positioned at a second side of the gate structure. The predetermined conductive type can be P type or N type. A fabricating process of the resistor can be integrated into a conventional MOS transistor fabricating process. Moreover, the resistor has better heat dissipation than conventional resistors.

### BACKGROUND OF THE INVENTION

1. Field of the Invention

The present invention relates to resistor structures and methods of making the resistor structures in the present invention.

2. Description of the Prior Art

A resistor is a two-terminal electrical or electronic component that resists an electric current by producing a voltage drop between its terminals. The resistance is equal to the voltage drop across the resistor divided by the current through the resistor. Resistors, such as polysilicon resistors, diffusion resistors, and metal-film resistors are used widely in semiconductor devices.

Generally speaking, polysilicon resistors include a doped polysilicon film. The resistance of the polysilicon resistors can be controlled by the doping concentration in the polysilicon layer. Diffusion resistors are formed by doping a semiconductor substrate to form a diffusion layer, and then using a thermal diffusion method to activate the dopants in the diffusion layer and adjust the resistance of the diffusion resistors. Normally, polysilicon resistors and diffusion resistors have a sandwich-like structure with a high resistance region between two low resistance ends. The low resistance ends are provided for forming interconnection contact plugs to connect the resistor with other wirings. The high resistance region is used to provide a high resistance to satisfy circuit design or device demands. The metal-film resistors can be formed by depositing a layer of metal, such as a nickel-chrome alloy on the substrate. Then, after removing unneeded portions of the metal layer by an etching process, the rest of the metal layer forms a metal-film resistor. The metal layer can be deposited by an evaporation sputtering process, or another deposition process.

The above-mentioned resistors do not have a switching function, which means that the resistance of the above-mentioned resistors cannot be turned on or off by electronic signals. In addition, resistance of the metal-film resistors should be changed by altering the thickness of film or changing the deposited metal. Therefore, an improved resistor is presented in the present invention. The resistor in the present invention can be integrated into present semiconductor processes. Furthermore, the aforesaid resistor provides a variety of resistances through different design of its structure, and has high integration. Moreover, the resistance of the resistors in the present invention can be adjusted by an electronic signal.

### SUMMARY OF THE INVENTION

The present invention relates to resistor structures and methods of making the resistor structures in the present invention.

According to the present invention, a resistor structure includes a substrate, a well of a predetermined conductive type positioned in the substrate, a conductor positioned on the substrate, a insulator positioned between the conductor and the substrate, a first doping region of the predetermined conductive type positioned at a first side of the conductor, a second doping region of the predetermined conductive type positioned at a second side of the conductor. The above-mentioned structure further comprises a first extended doping region containing the predetermined conductive type, a second extended doping region containing the predetermined conductive type, a cap and a spacer positioned on the conductor, wherein the first extended doping region is positioned in the well and adjacent to the first doping region and the conductor and the second extended doping region is positioned in the well and adjacent to the second doping region and the conductor.

According to the present invention, a method of fabricating a resistor structure includes: first, providing a substrate, next forming a well containing a predetermined conductive type in the substrate, then forming a gate structure on the surface of the well. The gate structure separates the well into a first side and a second side. Next, a first extended doping region containing the predetermined conductive type is formed in the first side of the gate structure, and a second extended doping region containing the predetermined conductive type is formed in the second side of the gate structure. Then, a spacer is formed on the gate structure. Finally, a first doping region and a second doping region are formed in the substrate under two sides of the gate structure. The first extended doping region and the second extended doping region can be fabricated optionally by different requirements.

The fabricating process of the resistor structure in the present invention can be integrated into the conventional MOS transistor fabricating process. Moreover, the resistor in the present has better heat dissipation than conventional resistors. In addition, the resistor of the present invention can provide a variety of resistances by different design of its structure. Moreover, the resistance of the resistors in the present invention can be adjusted by an electronic signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a resistor structure according to a preferred embodiment of the present invention.

FIG. 2 to FIG. 4 are schematic diagrams illustrating a method for manufacturing the resistor structure according to the preferred embodiment of the present invention, and FIG. 4 also shows a resistor structure fabricated by the aforesaid method.

FIG. 5 is a varied type of the resistor structure of FIG. 4.

FIG. 6 is a varied type of the resistor structure according to the fabricating process shown in FIG. 2 to FIG. 4.

FIG. 7 is a varied type of the resistor structure of FIG. 6.

FIG. 8 is another varied type of the resistor structure according to the fabricating process shown in FIG. 2 to FIG. 4.

FIG. 9 is a varied type of the resistor structure of FIG. 8.

FIG. 10 to FIG. 12 are schematic diagrams illustrating another method for manufacturing the resistor structure according to another embodiment of the present invention, and FIG. 12 also shows a resistor structure fabricated by the aforesaid method.

FIG. 13 is a varied type of the resistor structure of FIG. 12.

FIG. 14 is a varied type of the resistor structure fabricated according to the fabricating process shown in FIG. 10 to FIG. 12.

FIG. 15 is a varied type of the resistor structure of FIG. 14.

FIG. 16 is a varied type of the resistor structure fabricated according to the fabricating process shown in FIG. 10 to FIG. 12.

FIG. 17 is a varied type of the resistor structure of FIG. 16.

FIG. 18 shows a diagram of a series connection formed of the resistor structures of the present invention.

FIG. 19 shows a diagram of a parallel connection formed of the resistor structures of the present invention.

### DETAILED DESCRIPTION

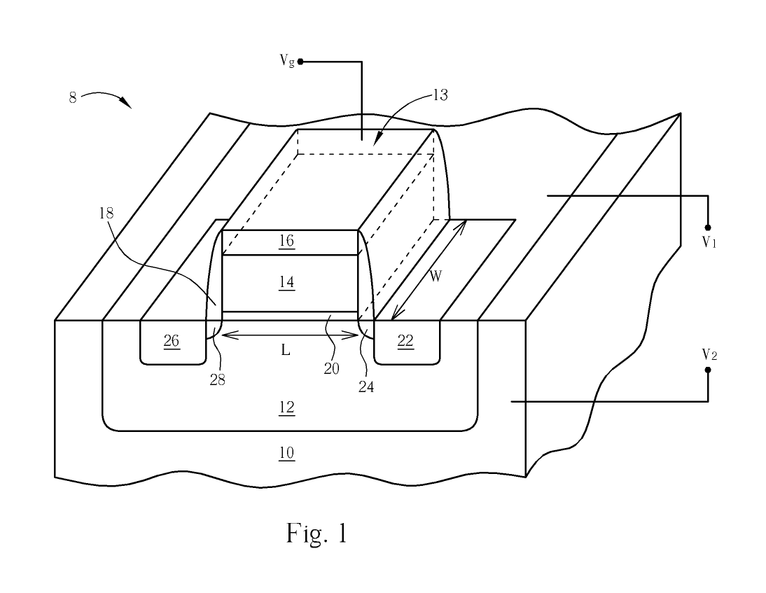

FIG. 1 shows a resistor structure according to a preferred embodiment in the present invention. As shown in FIG. 1, a resistor structure 8 includes a substrate 10, a well 12 of a predetermined conductive type positioned in the substrate 10, a gate structure 13 having length L and width W positioned on the substrate 10, a cap 16 and a spacer 18 positioned on the gate structure 13, a first doping region 22 of the predetermined conductive type positioned in the substrate 10 under a first side of the gate structure 13, a second doping region 26 of the predetermined conductive type positioned in the substrate 10 under a second side of the gate structure 13. The gate structure 13 further includes a conductor 14 composed of polysilicon, silicide, metal, or other conductive materials, and an insulator 20 composed of silicon oxide, silicon nitride or other dielectric materials. The conductor 14 is positioned on the substrate 10 and the insulator 20 is positioned between the conductor 14 and the substrate 10. Furthermore, in the preferred embodiment of the present invention, the resistor structure 8 can further comprises a first extended doping region 24 containing the predetermined conductive type, and a second extended doping region 28 containing the predetermined conductive type. The first extended doping region 24 is positioned in the substrate 10 and adjacent to the first doping region 22, and the second extended doping region 28 is positioned in the substrate 10 and adjacent to the second doping region 26.

In the preferred embodiment of present invention, the predetermined conductive type can be P type or N type. Therefore, the first doping region 22 and the second doping region 26 can be the connection ends of the resistor structure 8. It is noteworthy that the predetermined conductive type in the well 12, the first doping region 22, the second doping region 26, the first extended doping region 24 and the second extended doping region 28 can be formed by adding elements from the 3A group, such as boron (B), aluminum (Al), gallium (Ga), indium (In), and their combinations as P-type dopants, by adding elements from the 5A group, such as phosphorous (P), arsenic (As), antimony (Sb), or their combinations as N-type dopants, or by adding P-type and N-type dopants simultaneously, then adjusting the relative concentrations of the P-type and N-type dopants to form the predetermined conductive type. In other words, the resistance of the resistor structure 8 in the present invention can be controlled by adjusting the concentration(s) of the dopant(s).

Moreover, the resistance of the resistor structure 8 can also be changed by altering the length L and the width W of the conductor 14. For example, the resistance can be increased by increasing the length L or decreasing the width W, or the resistance can be decreased by decreasing the length L or increasing the width W. When the area of the cross-section is larger, the space for electrons to flow through is larger, so wider width W leads to a smaller resistance. On the contrary, the longer the length L is, the higher the resistance will be, because more collisions of electrons happen when the route is longer. In addition, the resistance of the resistor structure 8 can also be controlled by applying a voltage V_{g} to the conductor 14, by applying a voltage V₁ to the well 12, or applying a voltage V₂ to the substrate 10. For example, when V_{g} is applied to the conductor 14, the dopant in the area between the first doping region 22 and the second doping region 26 will be coupled. Then, the concentration between the first doping region 22 and the second doping region 26 is altered, leading to a change of the resistance. On the contrary, when V_{g} is removed, the resistance of the resistor structure 8 returns to the predetermined resistance.

Another feature in the present invention is a method of fabricating the resistor structure, which can be integrated into a conventional MOS fabricating process. These and other objectives will no doubt become obvious to those of ordinary skill in the art after reading the following detailed description of the preferred embodiment that is illustrated in the various figures and drawings.

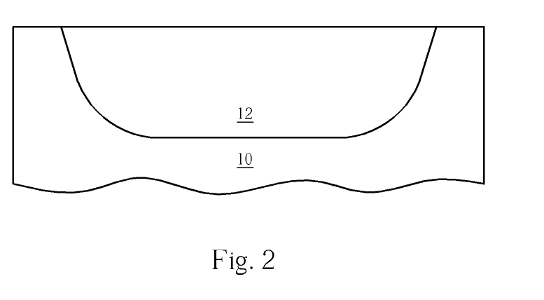

FIG. 2 to FIG. 4 are schematic diagrams illustrating a method for manufacturing the resistor structure according to the preferred embodiment of the present invention. As shown in FIG. 2, first, a substrate 10 is provided. Next, a MOS well fabrication process is performed to form a well 12 containing a predetermined conductive type, and other wells (not shown) are formed in another active area. For example, an N-type well 12 is formed in the substrate 10 if the predetermined conductive type is N-type, and the same mask and implantation process are used to form an N-type well for PMOS (not shown).

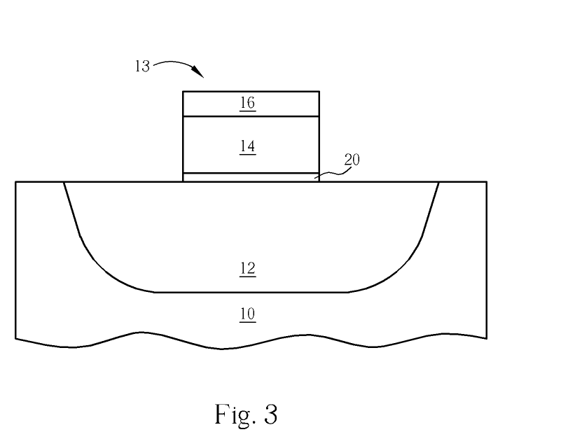

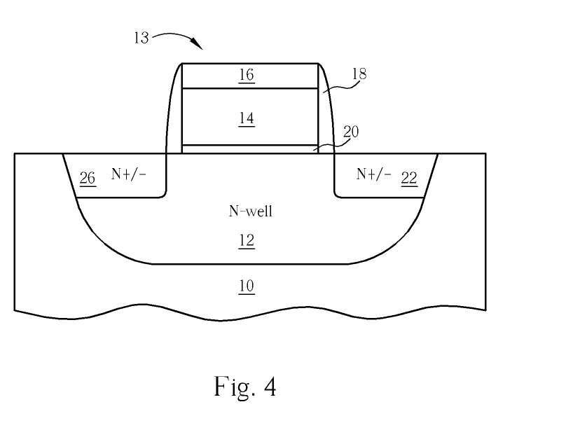

As shown in FIG. 3, a gate structure 13 is formed on the well 12, wherein the process of forming the gate structure 13 is performed at the same step as the process of forming the gate structure in the MOS. Meanwhile, other gate structures are formed on another active area (not shown). In other words, a dielectric layer (not shown) composed of silicon oxide, silicon nitride, or other dielectric materials, is formed. Following that, a conductor composed of polysilicon, silicide, metal, or other conductive materials is formed. Then, a liner (not shown) is optionally formed according to product requirements. Next, a lithography process is performed to form an insulator 20, a conductor 14, and a cap 16 positioned in order on the well 12 to compose a gate structure 13. The gate structure 13 separates the well 12 into two opposite sites: a first side and a second side, where a first doping region 22 and a second doping region 26 are going to form in following steps. As shown in FIG. 4, a spacer 18 is formed on the gate structure 13, a first doping region 22 of the predetermined conductive type, and a second doping region 26 of the predetermined conductive type in the well 12. The abovementioned spacer 18 and the doping regions 22 and 26 are formed by a spacer fabrication process and an ion implantation process in the conventional MOS fabricating process, respectively. Finally, a cap 16 is formed on the gate structure 13. Similarly, an N-type first doping region 22 and an N-type second doping region 26 are formed in the substrate 10 to be the connection ends if the predetermined conductive type is N-type, meanwhile using the same mask and implantation process to form source/drain regions for NMOS transistors in other active areas (not shown). In addition, the cap 16 and the spacer 18 are option in this embodiment.

In the embodiment mentioned above, the predetermined conductive type of the first doping region 22 and the second doping region 26 can be formed by only adding N-type dopant, or by adding both P-type and N-type dopant simultaneously, then by adjusting the relative concentrations of the P-type and N-type dopants to form the predetermined conductive type. The predetermined conductive type in this embodiment is N-type. Therefore, as shown in FIG. 4, the resistor structure formed by the method disclosed above includes: a substrate 10, a well 12 of a predetermined conductive type positioned in the substrate, a conductor 14 positioned on the substrate 10, an insulator 20 positioned between the conductor 14 and the substrate 10, a cap 16 and a spacer 18 positioned on the conductor 14, a first doping region 22 of the predetermined conductive type positioned at the first side of the conductor 14, and a second doping region 26 of the predetermined conductive type positioned at the second side of the conductor 14. The conductor 14 and the insulator 20 make up a gate structure 13. In addition, the predetermined conductive type in the well 12, the first doping region 22, and the second doping region 26 can be formed by only adding N-type dopant, or by adding both P-type and N-type, dopants simultaneously, then by adjusting the relative concentrations of the P-type and N-type dopants to form the predetermined conductive type. Furthermore, the concentrations of the dopant in the first doping region 22 and the second doping region 26 can be different, for example, by adding different concentrations of N-type or P-type dopants in the first doping region 22 and the second doping region 26 to form different final concentrations of the predetermined conductive type. That means, the concentration of predetermined conductive type in the first doping region 22 and the second doping region 26 can be different which allows for a variety of resistances.

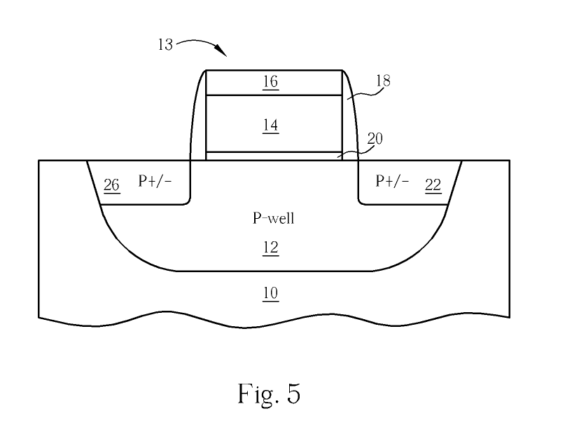

According to another preferred embodiment of fabricating the resistor structure in the present invention, the predetermined conductive type in this embodiment is P-type, and the rest of the fabrication steps are the same as those described in FIG. 2 to FIG. 4. The resistor structure of this embodiment is shown in FIG. 5. FIG. 5 can be taken as a varied type of FIG. 4. The difference between FIG. 5 and FIG. 4 is that the predetermined conductive type in FIG. 5 is P-type, such as boron (B), aluminum (Al), gallium (Ga), indium (In), or their combinations.

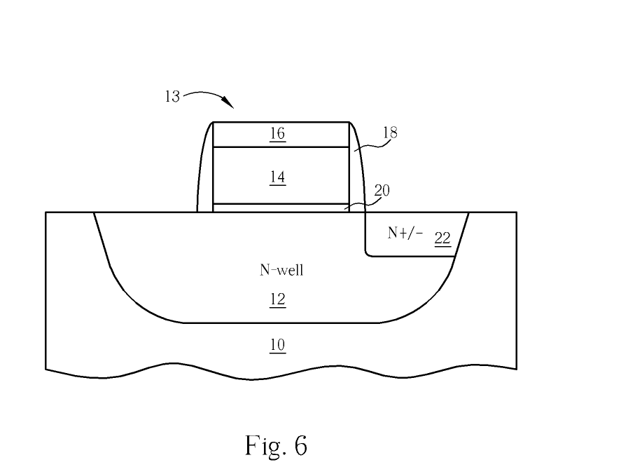

Another variation of the fabrication process and the resistor structure in FIG. 2 to FIG. 4 is that the second doping region 26 is not disposed and the rest of the steps remain the same as in FIG. 2 to FIG. 4. The resistor structure fabricated by this method is shown in FIG. 6, which includes: a substrate 10, a well 12 of a predetermined conductive type positioned in the substrate, a conductor 14 positioned on the substrate 10, an insulator 20 positioned between the conductor 14 and the substrate 10, a cap 16 and a spacer 18 positioned on the conductor 14, and a first doping region 22 of the predetermined conductive type positioned at a side of the conductor 14. The conductor 14 and the insulator 20 make up a gate structure 13. In addition, the predetermined conductive type in the well 12 and the first doping region 22 can be formed by only adding N-type dopant, or by adding P-type and N-type dopants simultaneously, then by adjusting the relative concentrations of the P-type and N-type dopants to form the predetermined conductive type.

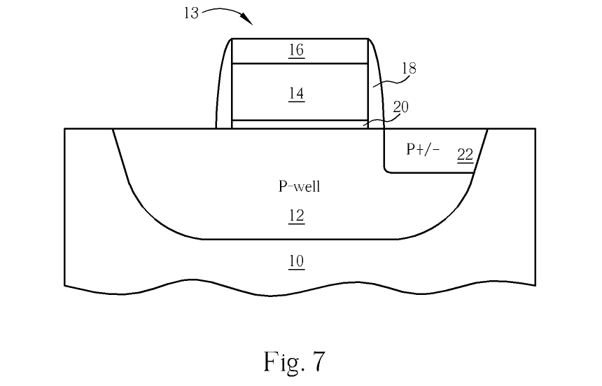

FIG. 7 can be taken as a varied type of FIG. 6. The difference between FIG. 7 and FIG. 6 is that the predetermined conductive type in FIG. 7 is P-type, formed by dopants such as boron (B), aluminum (Al), gallium (Ga), indium (In), or their combinations. The other fabrication steps are identical to those in FIG. 6.

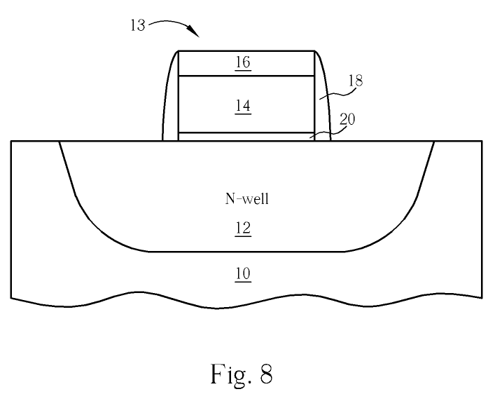

Yet another variation of the fabricating process and the resistor structure in FIG. 2 to FIG. 4 is that the first doping region 22 and the second doping region 26 are not disposed, and the remaining steps are the same as in FIG. 2 to FIG. 4. The resistor structure fabricated by this method is shown in FIG. 8, which includes: a substrate 10, a well 12 of a predetermined conductive type positioned in the substrate, a conductor 14 positioned on the substrate 10, an insulator 20 positioned between the conductor 14 and the substrate 10, and a cap 16 and a spacer 18 positioned on the conductor 14. The conductor 14 and the insulator 20 make up a gate structure 13. In addition, the predetermined conductive type in the well 12 can be formed by only adding N-type dopant, or by adding P-type and N-type dopants simultaneously, then by adjusting the relative concentrations of the P-type and N-type dopants to form the predetermined conductive type.

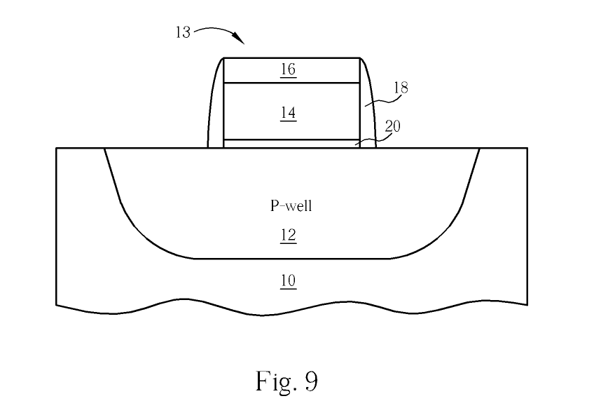

FIG. 9 can be taken as a varied type of FIG. 8. The difference between FIG. 9 and FIG. 8 is that the predetermined conductive type in FIG. 9 is P-type, formed by dopants such as boron (B), aluminum (Al), gallium (Ga), indium (In), or their combinations, and the other fabricating steps are identical to those in FIG. 8.

So far, the embodiments mentioned above have symmetrical or asymmetrical doping regions. It is noteworthy that the resistance of the resistors can be adjusted by altering the doping concentrations in the well or doping regions. Moreover, the resistance of resistors in the embodiments mentioned above can also be changed by altering the length L and the width W of the conductor 14, and applying a voltage V_{g} to the conductor 14, applying a voltage V₁ to the well 12, or applying a voltage V₂ to the substrate 10.

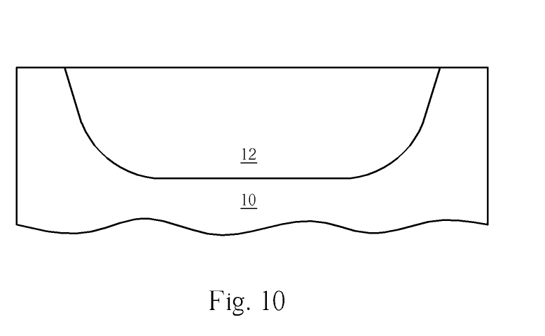

FIG. 10 to FIG. 12 are schematic diagrams illustrating another method of manufacturing the resistor according to another embodiment of the present invention. To simplify the illustration, same elements will use the same numerals as FIG. 2 to FIG. 4. As shown in FIG. 10, first, a substrate 10 is provided. Next, a MOS well fabrication process is performed to form a well 12 containing a predetermined conductive type, and other wells (not shown) are formed in another active area. For example, an N-type well 12 is formed in the substrate 10 if the predetermined conductive type is N-type, meanwhile using the same mask and the same implantation process to form an N-type well for PMOS transistors (not shown).

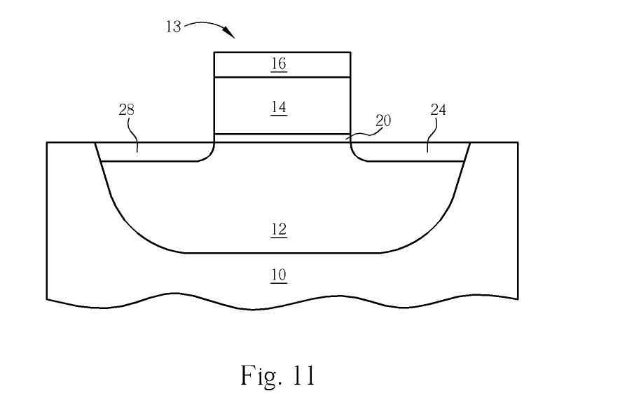

As shown in FIG. 11, a gate structure 13 including a conductor 14 and an insulator is formed on the well 12. The process of forming the gate structure 13 is the same step as the process of forming the gate structure in the MOS. Following that, a cap 16 is formed on the gate structure 13. Then, other gate structures are formed on another active area (not shown). The gate structure 13 separates the well 12 into two opposite sides. After that, a first extended doping region 24 containing the predetermined conductive type and a second extended doping region 28 containing the predetermined conductive type are formed at a first side and a second side of the conductor 14 by performing a lightly doped drain process in the conventional MOS fabrication process. An N-type first extended doping region 24 and an N-type second extended doping region 28 are formed in the substrate 10 in the same steps as forming N-type LDD regions for NMOS in other active areas (not shown). In addition, the cap 16 is optional in this embodiment.

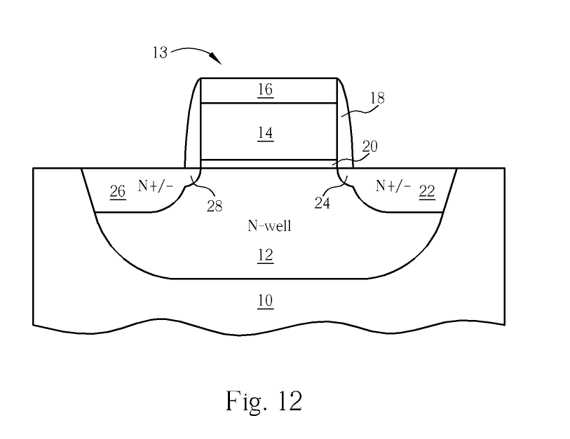

Then, a spacer 18 is formed on the gate structure 13. Next, as shown in FIG. 12, the gate structure 13 and the spacer 18 are taken as a mask to form a first doping region 22 of the predetermined conductive type and a second doping region 26 of the predetermined conductive type adjacent to the first extended doping region 24 and the second extended doping region 28, respectively. Similarly, an N-type first doping region 22 and an N-type second doping region 26 are formed in the substrate 10 to be the connection ends if the predetermined conductive type is N-type, meanwhile using the same mask and implantation process to form source/drain region for NMOS transistors in other active areas (not shown). In addition, the first doping region 22 of the predetermined conductive type and the second doping region 26 can be formed in advance. Then, after the spacer 18 is removed, the first extended doping region 24 and the second extended doping region 28 can be formed.

In this embodiment, the first doping region 22 and the second doping region 26 can be formed by only adding N-type dopant, or by adding P-type and N-type dopants simultaneously, then by adjusting the relative concentrations of the P-type and N-type dopants to form the predetermined conductive type. The predetermined conductive type in this embodiment is N-type. Therefore, as shown in FIG. 12, the resistor structure formed by the method disclosed above includes: a substrate 10, a well 12 of a predetermined conductive type positioned in the substrate 10, a conductor 14 positioned on the substrate 10, an insulator 20 positioned between the conductor 14 and the substrate 10, and a cap 16 and a spacer 18 positioned on the conductor 14. The conductor 14 and the insulator 20 make up a gate structure 13. Moreover, the above-mentioned resistor structure further comprises the first extended doping region 24 of the predetermined conductive type and the second extended doping region 28 of the predetermined conductive type adjacent to the first doping region 22 and the second extended doping region 26, respectively. In addition, the well 12, the first doping region 22, the second doping region 26, the first extended doping region 24, and the second extended doping region 28 either comprise only N-type dopant, or both N-type and P-type dopants, the relative concentrations of the N-type and P-type dopants adjusted to form the predetermined conductive type. Furthermore, the doping concentrations in the first doping region 22 and the second doping region 26 can be different, and the doping concentration in the first extended doping region 24 the second extended doping region 28 can be different, as well. For example, different concentrations of N-type or P-type dopants can be added in the first doping region 22 and the second doping region 26 to form different final concentrations of the predetermined conductive type. In this way, the concentrations of the predetermined conductive type in the first doping region 22 and the second doping region 26 can be different, and a variety of resistances are available. In addition, the cap 16 and the spacer 18 can be formed or removed based on product requirements.

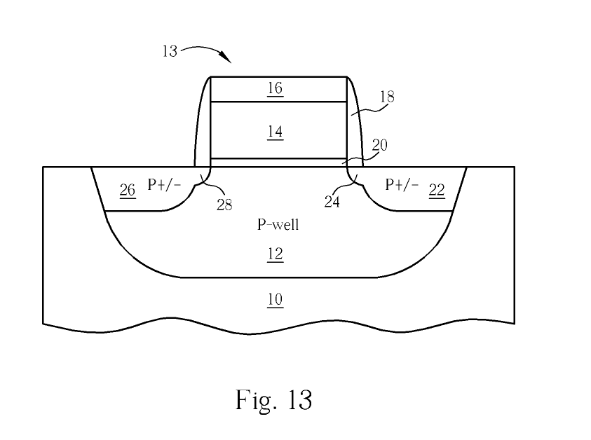

According to another preferred embodiment for fabricating the resistor structure in the present invention, the predetermined conductive type in this embodiment is P-type, and the rest of the fabrication steps are the same as those described in FIG. 10 to FIG. 12. The resistor structure of this embodiment is shown in FIG. 13. FIG. 13 can be taken as a varied type of FIG. 12, the difference between FIG. 13 and FIG. 12 being that the predetermined conductive type in FIG. 13 is P-type, formed of dopants such as boron (B), aluminum (Al), gallium (Ga), indium (In), or their combinations.

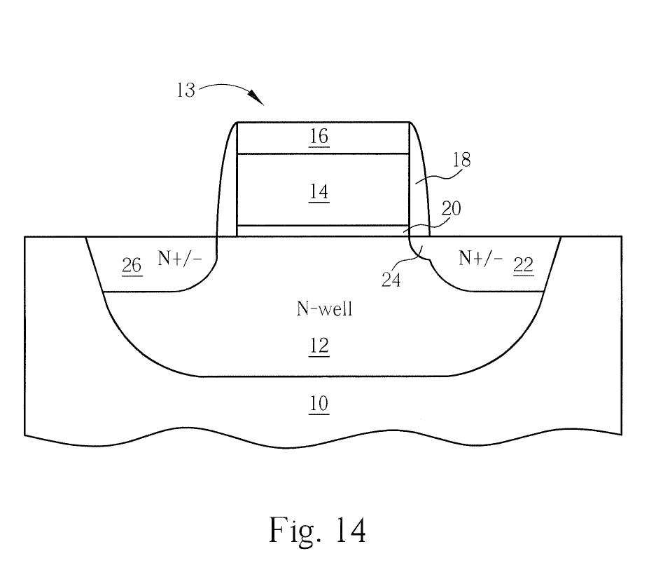

Another variation of the fabrication process and the resistor structure in FIG. 10 to FIG. 12 is not disposing the second extended doping region 28, while keeping the remaining steps the same as in FIG. 10 to FIG. 12. The resistor structure fabricated by this method is shown in FIG. 14, which includes: a substrate 10, a well 12 of a predetermined conductive type positioned in the substrate 10, a conductor 14 positioned on the substrate 10, an insulator 20 positioned between the conductor 14 and the substrate 10, and a cap 16 and a spacer 18 positioned on the conductor 14. The conductor 14 and the insulator 20 make up a gate structure 13. Moreover, the above-mentioned resistor structure further comprises a first extended doping region 24 of the predetermined conductive type adjacent to the first doping region 22. In addition, the well 12, the first doping region 22, the second doping region 26, and the first extended doping region 24 either comprise only N-type dopants, or both N-type and P-type dopants, where the relative concentrations of the N-type and P-type dopants can be adjusted to form the predetermined conductive type. The doping concentration in the first doping region 22 and the second doping region 26 can be different. For example, different concentrations of N-type or P-type dopants can be added in the first doping region 22 and the second doping region 26 to form different final concentrations of the predetermined conductive type. In this way, the concentration of the predetermined conductive type in the first doping region 22 and the second doping region 26 can be different, and a variety of resistances can be offered. In addition, the cap 16 and the spacer 18 can be formed or removed according to different requirements.

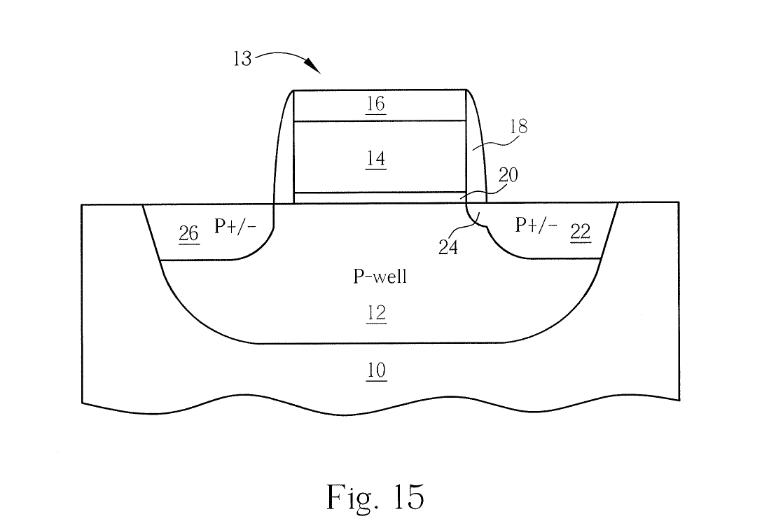

FIG. 15 can be taken as a varied type of FIG. 14. The difference between FIG. 15 and FIG. 14 is that the predetermined conductive type in FIG. 15 is P-type, formed by dopants such as boron (B), aluminum (Al), gallium (Ga), indium (In), or their combinations, and the other fabricating steps are identical to those in FIG. 14.

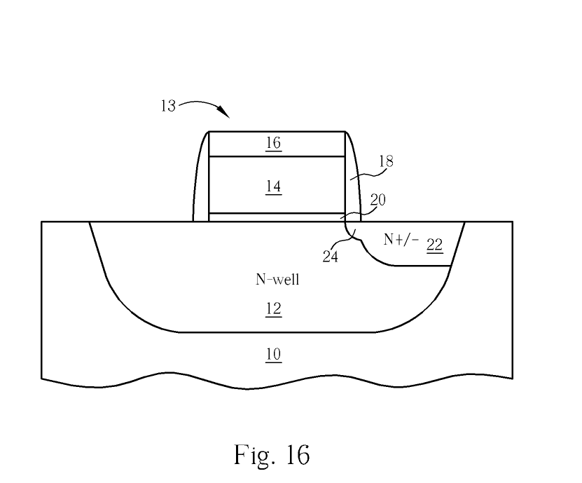

Yet another variation of the fabrication process and the resistor structure in FIG. 10 to FIG. 12 is not disposing the second doping region 26 and the second extended doping region 28, the remaining steps being the same as those of FIG. 10 to FIG. 12. The resistor structure fabricated by this method is shown in FIG. 16, which includes: a substrate 10, a well 12 of a predetermined conductive type positioned in the substrate 10, a conductor 14 positioned on the substrate 10, an insulator 20 positioned between the conductor 14 and the substrate 10, and a cap 16 and a spacer 18 positioned on the conductor 14. The conductor 14 and the insulator 20 make up a gate structure 13. Moreover, the above-mentioned resistor structure further comprises a first extended doping region 24 of the predetermined conductive type adjacent to the first doping region 22. In addition, the well 12, the first doping region 22, and the first extended doping region 24 each comprise either only N-type dopant, or both N-type and P-type dopants, in which adjusting the relative concentrations of the N-type and P-type dopants forms the predetermined conductive type. In addition, the cap 16 and the spacer 18 can be formed or removed according to different requirements.

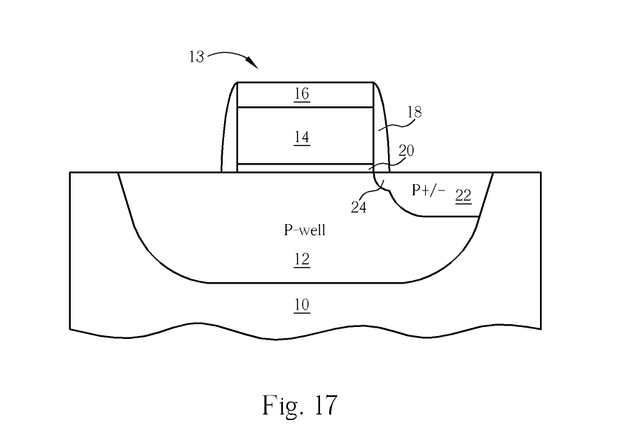

FIG. 17 can be taken as a varied type of FIG. 16. The difference between FIG. 17 and FIG. 16 is that the predetermined conductive type in FIG. 17 is P-type, formed by dopants such as boron (B), aluminum (Al), gallium (Ga), indium (In), or their combinations, and the other fabrication steps are identical to those in FIG. 16.

So far, the embodiments mentioned above have symmetrical or asymmetrical doping regions. It is noteworthy that the resistance of the resistors can be adjusted by altering the doping concentrations in the well or doping regions. Moreover, the resistance of resistors in the embodiments mentioned above can also be changed by altering the length L and the width W of the conductor 14, and by applying a voltage V_{g} to the conductor 14, applying a voltage V₁ to the well 12, or applying a voltage V₂ to the substrate 10. Furthermore, the resistor can be turned on or off by controlling V_{g}, V₁ and V₂. In order to make the figures simple and clear, the length L, the width W, and the voltages V_{g}, V₁ and V₂ are not shown in FIG. 2 to FIG. 17. The corresponding locations of the length L, the width W, and the voltages V_{g}, V₁, and V₂ are only depicted in FIG. 1.

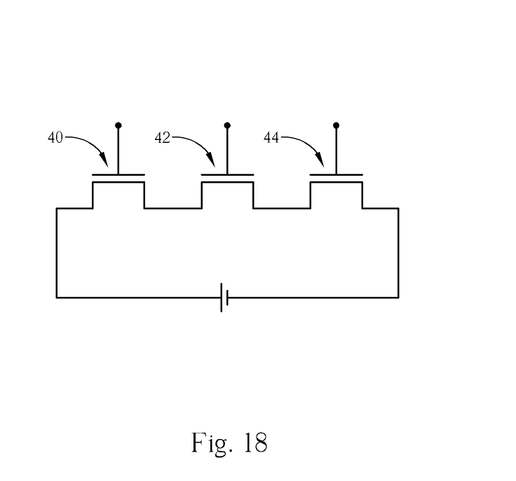

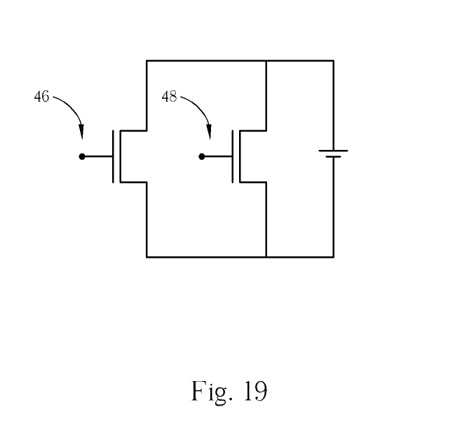

The resistor structure in the present invention can be applied to a series connection or a parallel connection. FIG. 18 shows a diagram of a series connection formed by the resistor structures in the present invention. Assuming the resistance of every resistor 40, 42, 44 is 5 Ω, the resistance of this circuit is equal to 15 Ω. In addition, by applying voltage to one or more resistor structures, the total resistance of this circuit can be adjusted, because the conductor of every resistor is coupled to the dopant in every substrate. FIG. 19 shows a diagram of a parallel connection formed by the resistor structures in the present invention. Assuming the resistance of every resistor 40, 42, 44 is 5 Ω, the resistance of this circuit is equal to 0.4 Ω. In addition, by applying voltage to one or more resistor structures, the total resistance of this circuit can be adjusted.

As described above, the process in the present invention can be integrated into existing MOS fabrication processes. For example, in the resistor structure in the present invention, the N-type dopant can be implanted in the same steps as the well implantation in PMOS or source/drain implantation in NMOS. In addition, in the resistor structure in the present invention, P-type dopant can be implanted in the same steps as the well implantation in NMOS or source/drain implantation in PMOS. Moreover, the embodiments in the present invention can also be integrated into the salicide process in MOS to form a layer of salicide on the conductor and the doping regions.

Moreover, the resistor in the present invention has better heat dissipation than that of the conventional resistor, because the resistor is positioned on the substrate. Thus, the heat generated by the resistor can be dissipated through the substrate efficiently. Therefore the resistor is less sensitive to temperature variation than the conventional resistor. Furthermore, the resistor structure in the present invention can provide a variety of resistances by different design of its structure, and the resistance of the resistor structure can be adjusted by an electronic signal.

Those skilled in the art will readily observe that numerous modifications and alterations of the device and method may be made while retaining the teachings of the invention.

What is claimed is:

1. A resistor structure comprising:
a substrate comprising a well of a predetermined conductive type;
a conductor positioned on the substrate; and
an insulator positioned between the conductor and the substrate.

2. The resistor structure of claim 1, wherein the predetermined conductive type is P type.

3. The resistor structure of claim 1, further comprising a first doping region comprising the predetermined conductive type, wherein the first doping region is positioned in the well under a first side of the conductor.

4. The resistor structure of claim 3, wherein the well and the first doping region contain a P-type dopant.

5. The resistor structure of claim 4, wherein the well and the first doping region further comprise an N-type dopant, and the concentration of the N-type dopant is lower than the concentration of the P-type dopant contained in the first doping region and the second doping region.

6. The resistor structure of claim 3, further comprising a second doping region comprising the predetermined conductive type, wherein the second doping region is positioned in the well under a second side of the conductor.

7. The resistor structure of claim 6, wherein the well, the first doping region and the second doping region contain a P-type dopant.

8. The resistor structure of claim 7, wherein the well, the first doping region and the second doping region further comprise an N-type dopant, and the concentration of the N-type dopant is lower than the concentration of the P-type dopant contained in the first doping region and the second doping region.

9. The resistor structure of claim 1, wherein the predetermined conductive type is N type.

10. The resistor structure of claim 9, further comprising a first doping region comprising the predetermined conductive type, wherein the first doping region is positioned in the well under a first side of the conductor.

11. The resistor structure of claim 10, wherein the well and the first doping region contain a N-type dopant.

12. The resistor structure of claim 11, wherein the well and the first doping region further comprise an P-type dopant, and the concentration of the P-type dopant is lower than the concentration of the N-type dopant contained in the first doping region and the second doping region.

13. The resistor structure of claim 10, further comprising a second doping region comprising the predetermined conductive type, wherein the second doping region is positioned in the well under a second side of the conductor.

14. The resistor structure of claim 13, wherein the well, the first doping region and the second doping region contain a N-type dopant.

15. The resistor structure of claim 14, wherein the well, the first doping region and the second doping region further comprise an P-type dopant, and the concentration of the P-type dopant is lower than the concentration of the N-type dopant contained in the first doping region and the second doping region.

16. The resistor structure of claim 3, further comprising a first extended doping region containing the predetermined conductive type, wherein the first extended doping region is positioned in the well and adjacent to the first doping region and the conductor.

17. The resistor structure of claim 16, further comprising a second extended doping region containing the predetermined conductive type, wherein the second extended doping region is positioned in the well and adjacent to the second doping region and the conductor.

18. The resistor structure of claim 10, further comprising a first extended doping region containing the predetermined conductive type, wherein the first extended doping region is positioned in the well and adjacent to the first doping region and the conductor.

19. The resistor structure of claim 18, further comprising a second extended doping region containing the predetermined conductive type, wherein the second extended doping region is positioned in the well and adjacent to the second doping region and the conductor.

20. The resistor structure of claim 1, further comprising a cap positioned on the conductor.

21. The resistor structure of claim 1, further comprising a spacer positioned on the conductor.

22. The resistor structure of claim 1, wherein the conductor further comprises a width and a length, and the resistance of the resistor structure can be controlled by adjusting the width and the length.

23. The resistor structure of claim 1, wherein the resistance of the resistor structure can be controlled by adjusting the voltage of the well and the conductor.

24. The resistor structure of claim 1, wherein the resistor structure forms a series connection with an electric circuit.

25. The resistor structure of claim 1, wherein the resistor structure forms a parallel connection with an electric circuit.

26. A method of fabricating a resistor structure, comprising:
providing a substrate;
forming a well containing a predetermined conductive type in the substrate; and
forming a gate structure on the surface of the well, wherein the gate structure separates the well into a first side and a second side.

27. The method of claim 26, further comprising forming a first doping region containing the predetermined conductive type, wherein the first doping region is positioned in the well under the first side of the gate structure.

28. The method of claim 27, further comprising forming a second doping region containing the predetermined conductive type, wherein the second doping region is positioned in the well under the second side of the gate structure.

29. The method of claim 27, further comprising forming a first extended doping region containing the predetermined conductive type, wherein the first extended doping region is positioned in the well and adjacent to the first doping region and the conductor.

30. The method of claim 28, further comprising forming a second extended doping region containing the predetermined conductive type, wherein the second extended doping region is positioned in the well and adjacent to the second doping region and the conductor.

31. The method of claim 26, further comprising forming a cap positioned on the gate structure.

32. The method of claim 26, further comprising forming a spacer positioned on the gate structure.

33. The method of claim 26, wherein the predetermined conductive type is P type.

34. The method of claim 26, wherein the predetermined conductive type is N type.
